(19) United States
(12) Patent Application Publication
(10) Pub. No.: US 2022/0336781 A1
(43) Pub. Date: Oct. 20, 2022

(54) DISPLAY DEVICE

(71) Applicant: Samsung Display Co., Ltd., Yongin-si (KR)

(72) Inventors: JONGBEOM HONG, Yongin-si (KR); YONGSUB SHIM, Gwangmyeong-si (KR); CHIWOOK AN, Hwaseong-si (KR); HYUNDUCK CHO, Anyang-si (KR)

(21) Appl. No.: 17/572,078

(22) Filed: Jan. 10, 2022

(30) Foreign Application Priority Data
Apr. 19, 2021 (KR) 10-2021-0050424

(51) Int. Cl. H01L 51/52; H01L 27/32; G06F 3/041; G06F 3/044

(52) U.S. Cl. CPC H01L 51/5284; H01L 27/323; G06F 3/0412; G06F 3/0443; H01L 27/3216; H01L 27/3246; H01L 27/322

(57) ABSTRACT

A display device includes a display panel including a light emitting area, from which a light is emitted, and a peripheral area adjacent to the light emitting area, and a light blocking member disposed on the display panel to block the light. At least a portion of the light blocking member is disposed in the light emitting area, one side surface of the light blocking member is disposed in the light emitting area, and an opposing side surface of the light blocking member, which is opposite to the one side surface, is disposed closer to a center of the peripheral area than the one side surface is.

This application claims priority to Korean Patent Application No. 10-2021-0050424, filed on Apr. 19, 2021, and all the benefits accruing therefrom under 35 U.S.C. § 119, the content of which in its entirety is herein incorporated by reference.

### BACKGROUND

### 1. Field

The disclosure relates to a display device. More particularly, the disclosure relates to a display device having improved brightness retention rate.

### 2. Description of the Related Art

Display devices, such as televisions, monitors, smartphones, and tablet computers, which provide images to a user, include a display panel to display images. Recently, various types of display panel, such as a liquid crystal display panel, an organic light emitting display panel, an electrowetting display panel, an electrophoretic display panel, etc., are being developed.

In the display devices, a reflective phenomenon in which a natural light is reflected occurs. The reflective phenomenon reduces visibility of the display devices. The display devices may include an optical film to prevent the reflective phenomenon from occurring.

### SUMMARY

The disclosure provides a display device having improved brightness retention rate in a side surface compared with that in a front surface.

An embodiment of the invention provides a display device including a display panel including a light emitting area, from which a light is emitted, and a peripheral area adjacent to the light emitting area, and a light blocking member disposed on the display panel to block the light. In such an embodiment, at least a portion of the light blocking member is disposed in the light emitting area, one side surface of the light blocking member is disposed in the light emitting area, and an opposing side surface of the light blocking member, which is opposite to the one side surface, is disposed closer to a center of the peripheral area than the one side surface is.

In an embodiment, the light emitting area may include a first light emitting area from which a first light is emitted and a second light emitting area from which a second light having a wavelength different from the first light is emitted, and the light blocking member may include a first sub-light blocking member disposed in the first light emitting area and a second sub-light blocking member disposed in the second light emitting area.

In an embodiment, the first sub-light blocking member and the second sub-light blocking member may be spaced apart from each other with a first gap defined therebetween when viewed in a plan view, and the first gap may be defined to allow at least a portion thereof to overlap the peripheral area.

In an embodiment, the display device may further include an overcoat layer disposed on the display panel to cover the light blocking member.

In an embodiment, the display device may further include an input sensing unit disposed on the display panel, and the light blocking member may be disposed in the input sensing unit.

In an embodiment, the light blocking member may include a conductive layer.

In an embodiment, the conductive layer included in the light blocking member may be provided in plural, and an upper surface of an uppermost layer among the conductive layers may be blackened.

In an embodiment, the display device may further include an anti-reflective layer disposed on the display panel.

In an embodiment, the anti-reflective layer may include a plurality of color filters, and the light blocking member may be disposed in each of the plurality of color filters.

In an embodiment, the light blocking member has a black color.

In an embodiment, the light emitting area may include a first light emitting area from which a first light is emitted, and a second light emitting area from which a second light having a wavelength different from the first light is emitted, and the light blocking member may include a first sub-light blocking member disposed in the first light emitting area, and a second sub-light blocking member disposed in the second light emitting area. In such an embodiment, the plurality of color filters includes a first color filter overlapping the first light emitting area and a second color filter overlapping the second light emitting area. In such an embodiment, the first sub-light blocking member may include a material having a color different from a color of the first color filter, and the second sub-light blocking member may include a material having a color different from a color of the second color filter.

In an embodiment, the light blocking member may have a thickness equal to or greater than about 0.5 micrometers and equal to or smaller than about 2 micrometers.

In an embodiment, the light blocking member may have a width equal to or greater than about 0.5 micrometers and equal to or smaller than about 3 micrometers.

In an embodiment, the display device may further include an additional light blocking member overlapping the peripheral area.

In an embodiment, the light blocking member and the additional light blocking member may be spaced apart from each other with a second gap defined therebetween when viewed in a plan view.

In an embodiment, the opposing side surface of the light blocking member may be disposed at a boundary between the light emitting area and the peripheral area when viewed in a plan view.

An embodiment of the invention provides a display device including a display panel including a light emitting area and a peripheral area adjacent to the light emitting area, where the light emitting area includes a first light emitting area from which a first light is emitted and a second light emitting area from which a second light having a wavelength different from the first light is emitted, and a light blocking member disposed on the display panel to block a light. In such an embodiment, the light blocking member includes a first sub-light blocking member disposed in the first light emitting area and a second sub-light blocking member disposed in the second light emitting area. In such an embodiment, the first sub-light blocking member and the second sub-light blocking member are spaced apart from each other with a first gap defined therebetween when viewed in a plan view, and the first gap is defined to allow at least a portion thereof to overlap the peripheral area.

In an embodiment, the light emitting area may further include a third light emitting area from which a third light having a wavelength different from the first and second lights is emitted, and the light blocking member may further include a third sub-light blocking member disposed in the third light emitting area.

In an embodiment, the first light may be a blue light, the second light may be a green light, and the third light may be a red light.

In an embodiment, the display device may further include an anti-reflective layer disposed on the display panel and a window disposed on the anti-reflective layer.

According to embodiments, the display device has the structure in which a rate in which the brightness decreases in the side surface is smaller than a rate in which the brightness decreases in the front surface. Accordingly, the brightness retention rate in the side surface is improved compared with that in the front surface, and thus, a display efficiency of the display device is improved.

### BRIEF DESCRIPTION OF THE DRAWINGS

The above and other features of the disclosure will become readily apparent by reference to the following detailed description when considered in conjunction with the accompanying drawings, in which:

FIG. 1A is a perspective view showing a display device according to an embodiment of the disclosure;

FIG. 1B is an exploded perspective view showing a display device according to an embodiment of the disclosure;

FIGS. 1C and 1D are cross-sectional views showing display devices according to an embodiment of the disclosure;

FIG. 2 is a plan view showing a display panel according to an embodiment of the disclosure;

FIG. 3 is a plan view showing an input sensing unit according to an embodiment of the disclosure;

FIG. 4 is a plan view showing a display area according to an embodiment of the disclosure;

FIG. 5 is a cross-sectional view showing a display panel according to an embodiment of the disclosure;

FIG. 6 is a plan views showing a portion of a display device according to an embodiment of the disclosure;

FIG. 7A is a cross-sectional view showing a display module according to an embodiment of the disclosure;

FIG. 7B is an enlarged plan view showing a display module according to an embodiment of the disclosure;

FIGS. 8A and 9A are cross-sectional views showing display modules according to an embodiment of the disclosure;

FIGS. 8B and 9B are cross-sectional views showing a portion of display modules according to an embodiment of the disclosure; and

FIGS. 10A and 10B are cross-sectional views showing a portion of display modules according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the disclosure, it will be understood that when an element or layer is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. “Or” means “and/or.” As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. The terminology used herein is for the purpose of describing particular embodiments only and is not intended to be limiting. As used herein, the singular forms, “a”, “an” and “the” are intended to include the plural forms as well, unless the context clearly indicates otherwise. For example, “an element” has the same meaning as “at least one element,” unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be further understood that the terms “comprises” and/or “comprising,” or “includes” and/or “including”, when used in this specification, specify the presence of stated features, integers, steps, operations, elements, and/or components, but do not preclude the presence or addition of one or more other features, integers, steps, operations, elements, components, and/or groups thereof.

In the disclosure, when an element is referred to as being “directly connected” to another element, there are no intervening elements present between a layer, film region, or substrate and another layer, film, region, or substrate. For example, the term “directly connected” may mean that two layers or two members are disposed without employing additional adhesive therebetween.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

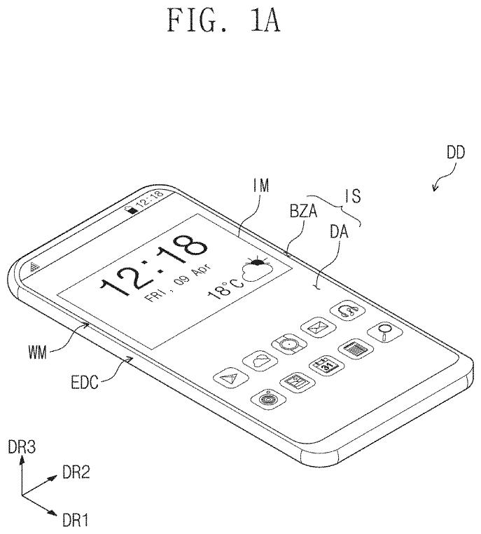

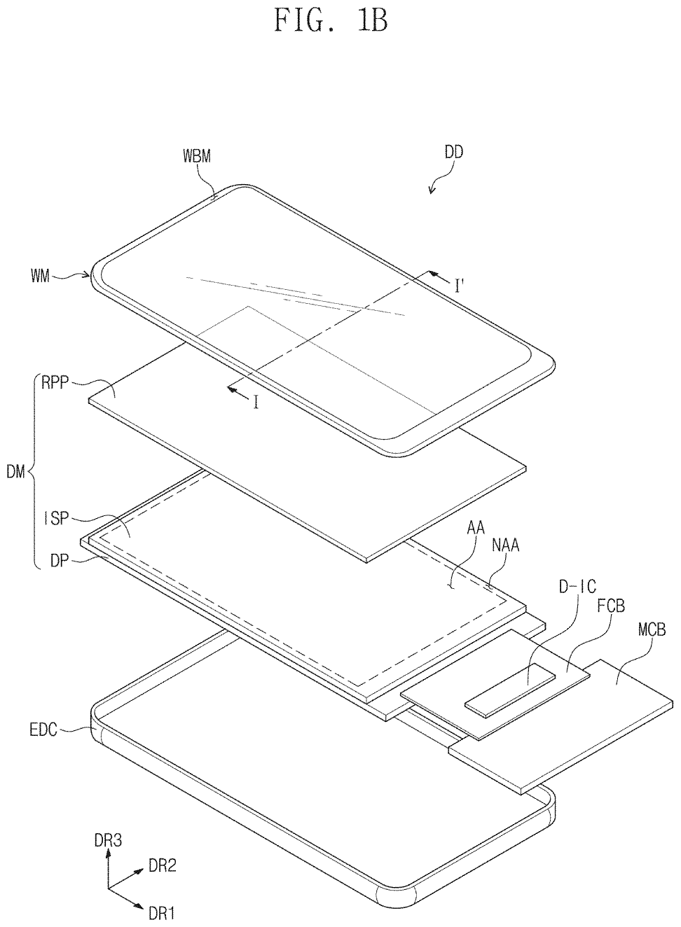

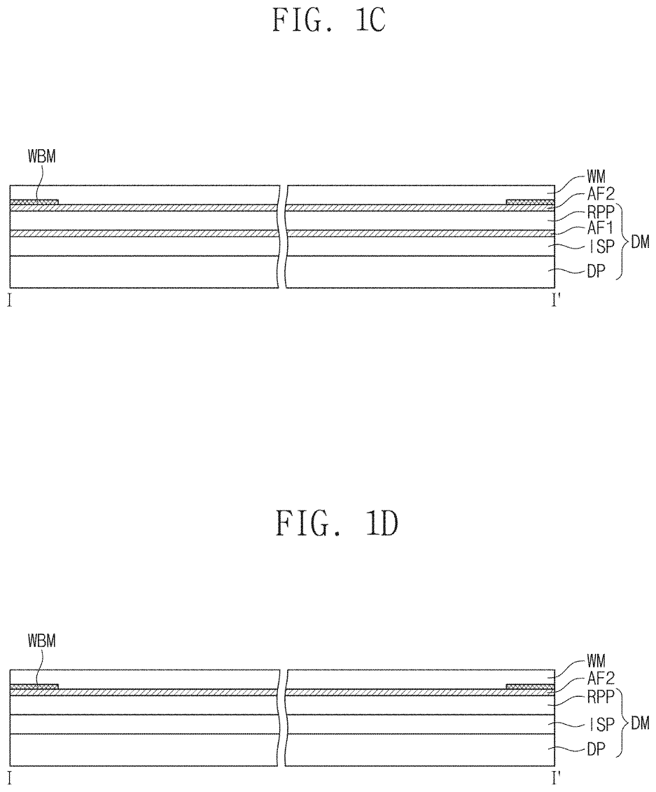

FIG. 1A is a perspective view showing a display device DD according to an embodiment of the disclosure. FIG. 1B is an exploded perspective view showing the display device DD according to an embodiment of the disclosure. FIGS. 1C and 1D are cross-sectional views taken along line I-I′ shown in FIG. 1B.

Referring to FIGS. 1A to 1D, an embodiment of the display device DD may be a device activated in response to electrical signals. The display device DD may include various types of display device. In one embodiment, for example, the display device DD may be applied to electronic devices, such as a smart watch, a tablet computer, a notebook computer, a computer, a smart television, or the like.

The display device DD may display an image IM toward a third direction DR3 through a display surface IS that is substantially parallel to each of a first direction DR1 and a second direction DR2. The display surface IS, through which the image IM is displayed, may correspond to a front surface of the display device DD. The image IM may include a video and a still image.

In an embodiment, front (or upper) and rear (or lower) surfaces of each member may be defined with respect to a direction in which the image IM is displayed. The front and rear surfaces are opposite to each other in the third direction DR3, and a normal line direction of each of the front and rear surfaces may be substantially parallel to the third direction DR3.

A separation distance in the third direction DR3 between the front surface and the rear surface may correspond to a thickness in the third direction DR3 of the display device DD. Herein, directions indicated by the first, second, and third directions DR1, DR2, and DR3 are relative to each other and may be changed in other directions.

In an embodiment, the display device DD may be rigid and have a bar, as shown in FIG. 1A, however, the display device DD is not limited thereto or thereby. According to an alternative embodiment, the display device DD may be a flexible display device, such as a foldable display device foldable with respect to a folding axis, a stretchable display device, a rollable display device, etc.

The display device DD may sense an external input applied thereto from the outside. The external input may include various forms of inputs provided from the outside of the display device DD.

In one embodiment, for example, the external inputs may include a proximity input (e.g., hovering) applied when approaching close to or adjacent to the display device DD at a predetermined distance as well as a touch input by a user's body (e.g., a user's hand). In an embodiment, the external inputs may be provided in the form of force, pressure, temperature, light, etc., however, it should not be limited thereto or thereby.

The front surface of the display device DD may include a display area DA and a bezel area BZA. The display area DA may be an area through which the image IM is displayed. The user may view the image IM through the display area DA. In one embodiment, for example, the display area DA may have a quadrangular shape with rounded vertices. Alternatively, the display area DA may have a variety of shapes and should not be particularly limited.

The bezel area BZA may be defined adjacent to the display area DA. The bezel area BZA may have a predetermined color. The bezel area BZA may surround the display area DA. Accordingly, the display area DA may have a shape defined by the bezel area BZA, for example. Alternatively, the bezel area BZA may be disposed adjacent to only one side of the display area DA or may be omitted. The display device DD may be variously modified and should not be particularly limited.

As shown in FIGS. 1B and 1D, an embodiment of the display device DD may include a window WM, an external case EDC, and a display module DM. The display module DM may include a display panel DP, an input sensing unit ISP, and an anti-reflective unit RPP.

The window WM may include a transparent material that transmits the image. In one embodiment, for example, the window WM may include a glass, sapphire, or plastic material. In an embodiment, the window WM may have a single-layer structure, however, it should not be limited thereto or thereby. According to an alternative embodiment, the window WM may include a plurality of layers. In an embodiment, although not shown in figure, the bezel area BZA of the display device DD may be defined by printing a material having a predetermined color on an area of the window WM. In one embodiment, for example, the window WM may include a bezel pattern WBM to define the bezel area BZA. The bezel pattern WBM may be a colored organic layer and may be formed by a coating method.

According to an embodiment, the display panel DP may be a light-emitting type display panel, however, it should not be particularly limited. In an embodiment, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod. Hereinafter, for convenience of description, embodiments where the display panel DP is the organic light emitting display panel will be described in detail.

In an embodiment, the input sensing unit ISP may be disposed directly on the display panel DP. According to an embodiment, the input sensing unit ISP may be formed on the display panel DP through successive processes. In such an embodiment where the input sensing unit ISP is disposed directly on the display panel DP, an adhesive film (not shown) may not be disposed between the input sensing unit ISP and the display panel DP. The display panel DP may generate the image, and the input sensing unit ISP may obtain coordinate information on the external input, e.g., a touch event.

The anti-reflective unit RPP may reduce a reflectance of an external light incident thereto from the above of the window WM. According to an embodiment, the anti-reflective unit RPP may include a retarder and a polarizer. The retarder may be a film type or liquid crystal coating type and may include a 212 retarder and/or a 214 retarder. The polarizer may be a film type or liquid crystal coating type. The film type polarizer may include a stretching type synthetic resin film, and the liquid crystal coating type polarizer may include liquid crystals aligned in a predetermined alignment. The retarder and the polarizer may be implemented as a single polarizing film. The anti-reflective unit RPP may further include a protective film disposed above or under the polarizing film.

According to an embodiment, the anti-reflective unit RPP may include color filters. The color filters may have a predetermined arrangement. The arrangement of the color filters may be determined based on emission colors of pixels included in the display panel DP. The anti-reflective unit RPP may further include a light blocking member disposed adjacent to the color filters. The color filters will be described in detail later.

According to an embodiment, the anti-reflective unit RPP may include a destructive interference structure. In one embodiment, for example, the destructive interference structure may include a first reflection layer and a second reflection layer, which are disposed in different layers from each other. A first reflection light and a second reflection light, which are reflected by the first reflection layer and the second reflection layer, respectively, may be destructively interfered with each other, and thus, the reflectance of the external light may be reduced.

In an embodiment shown in FIGS. 1C to 1D, among the input sensing unit ISP, the anti-reflective unit RPP, and the window WM, a component that is formed through the successive processes with another component is referred to as a “layer”. Among the input sensing unit ISP, the anti-reflective unit RPP, and the window WM, a component that is coupled to another component by the adhesive member is referred to as a “panel”. The panel may include a base layer for providing a base surface, e.g., a synthetic resin film, a composite film, or a glass substrate, however, the base layer may be omitted from the component that is referred to as the “layer”. In such an embodiment, the component that is referred to as the “layer” is disposed on the base surface provided by another component or layer.

The anti-reflective unit RPP may be referred to as an anti-reflective panel or an anti-reflective layer depending on the presence/absence of the base layer. In an embodiment, the window WM may be a panel type, and the input sensing unit ISP may be a layer type, however, they should not be limited thereto or thereby.

In an embodiment, the anti-reflective unit RPP may be disposed on the input sensing unit ISP. In such an embodiment, the anti-reflective unit RPP may be disposed between the input sensing unit ISP and the window WM. The input sensing unit ISP, the anti-reflective unit RPP, and the window WM may be coupled with each other by an adhesive film. In one embodiment, for example, as shown in FIG. 1C, a first adhesive film AF1 may be disposed between the input sensing unit ISP and the anti-reflective unit RPP, and a second adhesive film AF2 may be disposed between the anti-reflective unit RPP and the window WM.

Accordingly, the anti-reflective unit RPP may be coupled with the input sensing unit ISP by the first adhesive film AF1, and the window WM may be coupled with the anti-reflective unit RPP by the second adhesive film AF2. According to an embodiment, the first and second adhesive films AF1 and AF2 may include an optically clear adhesive film (“OCA”), however, the first and second adhesive films AF1 and AF2 should not be limited thereto or thereby. According to an alternative embodiment, the first and second adhesive films AF1 and AF2 may include a conventional adhesive. In one embodiment, for example, the first and second adhesive films AF1 and AF2 may include an optically clear resin (“OCR”) or a pressure sensitive adhesive film (“PSA”).

In an alternative embodiment, at least one selected from the first adhesive film AF1 and the second adhesive film AF2 may be omitted. In one embodiment, for example, as shown in FIG. 1D, the first adhesive film may be omitted, and the anti-reflective unit RPP may be disposed directly on the input sensing unit ISP. In such an embodiment where the anti-reflective unit RPP is disposed directly on the input sensing unit ISP, the anti-reflective unit RPP may include color filters and an additional light blocking member adjacent to the color filters.

The display module DM may display the image in response to electrical signals and may transmit/receive information on the external input. The display module DM may include an active area AA and a peripheral area NAA. The active area AA may be defined as an area through which the image provided from the display module DM transmits.

The peripheral area NAA may be defined adjacent to the active area AA. In one embodiment, for example, the peripheral area NAA may surround the active area AA, but not being limited thereto. Alternatively, the peripheral area NAA may be defined in various shapes and should not be particularly limited. According to an embodiment, the active area AA of the display module DM may correspond to at least a portion of the display area DA.

The display module DM may further include a main circuit board MCB, a flexible circuit board FCB, and a driving chip D-IC.

The main circuit board MCB may be connected to the flexible circuit board FCB and may be electrically connected to the display panel DP. The main circuit board MCB may include a plurality of driving elements. The driving elements may include a circuit to drive the display panel DP.

The flexible circuit board FCB may be connected to the display panel DP and may electrically connect the display panel DP to the main circuit board MCB. The driving chip D-IC may be mounted on the flexible circuit board FCB.

The driving chip D-IC may include driving elements, for example, a data driving circuit, to drive a pixel of the display panel DP. According to an embodiment, the display module DM includes a single flexible circuit board FCB, however, it should not be limited thereto or thereby. Alternatively, the flexible circuit board FCB may be provided in plural, and the flexible circuit board FCB may be connected to the display panel DP.

FIG. 1B shows an embodiment having a structure in which the driving chip D-IC is mounted on the flexible circuit board FCB, however, the disclosure should not be limited thereto or thereby. In one alternative embodiment, for example, the driving chip D-IC may be disposed directly on the display panel DP. In such an embodiment, a portion of the display panel DP on which the driving chip D-IC is mounted may be bent to be disposed on a rear surface of the display module DM.

The input sensing unit ISP may be electrically connected to the main circuit board MCB through the flexible circuit board FCB, however, the embodiment of the disclosure should not be limited thereto or thereby. Alternatively, the display module DM may further include a separate flexible circuit film to electrically connect the input sensing unit ISP to the main circuit board MCB.

The external case EDC may accommodate the display module DM. The external case EDC may be coupled with the window WM and may define an appearance of the display device DD. The external case EDC may absorb impacts applied thereto from the outside and may prevent foreign substance and moisture from entering the display module DM to protect components accommodated in the external case EDC. In one embodiment, for example, the external case EDC may be provided in a form in which a plurality of storage members is combined with each other.

According to an embodiment, the display device DD may further include an electronic module including various functional modules to operate the display module DM, a power supply module for supplying a power used for an overall operation of the display device DD, and a bracket coupled to the display module DM and/or the external case EDC to divide an inner space of the display device DD.

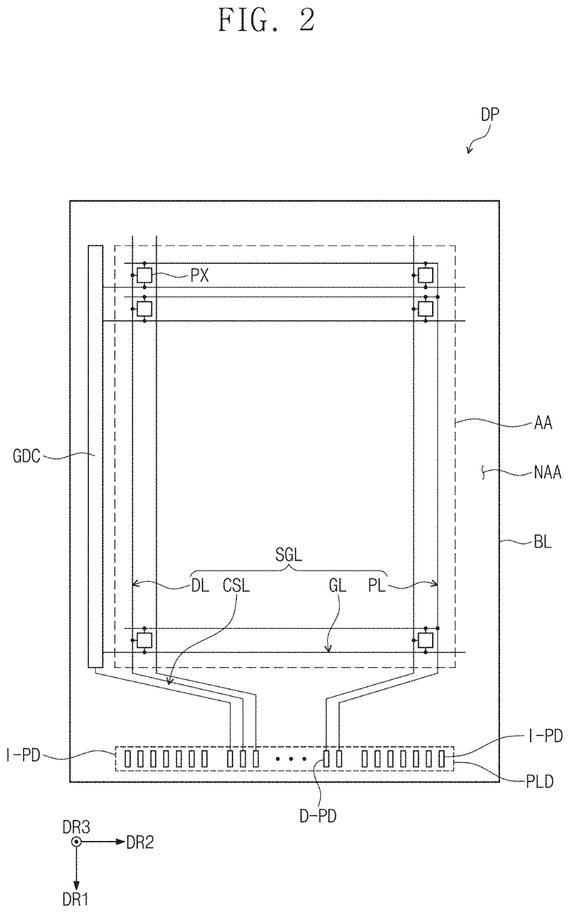

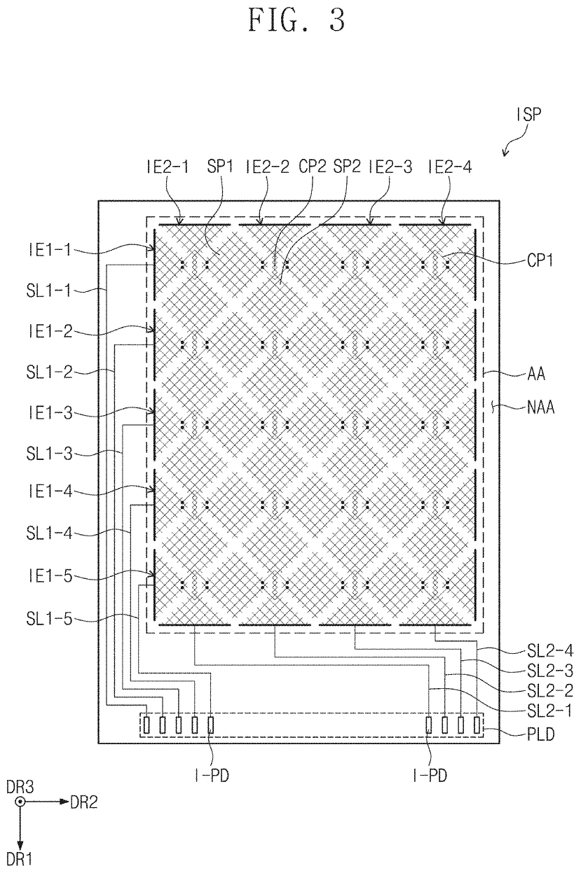

FIG. 2 is a plan view showing the display panel DP according to an embodiment of the disclosure, and FIG. 3 is a plan view showing the input sensing unit ISP according to an embodiment of the disclosure.

Referring to FIG. 2, an embodiment of the display panel DP may include a driving circuit GDC, a plurality of signal lines SGL, and a plurality of pixels PX. The display panel DP may further include a pad part PLD disposed in the peripheral area NAA. The pad part PLD may include pixel pads D-PD, each being connected to a corresponding signal line among the signal lines SGL.

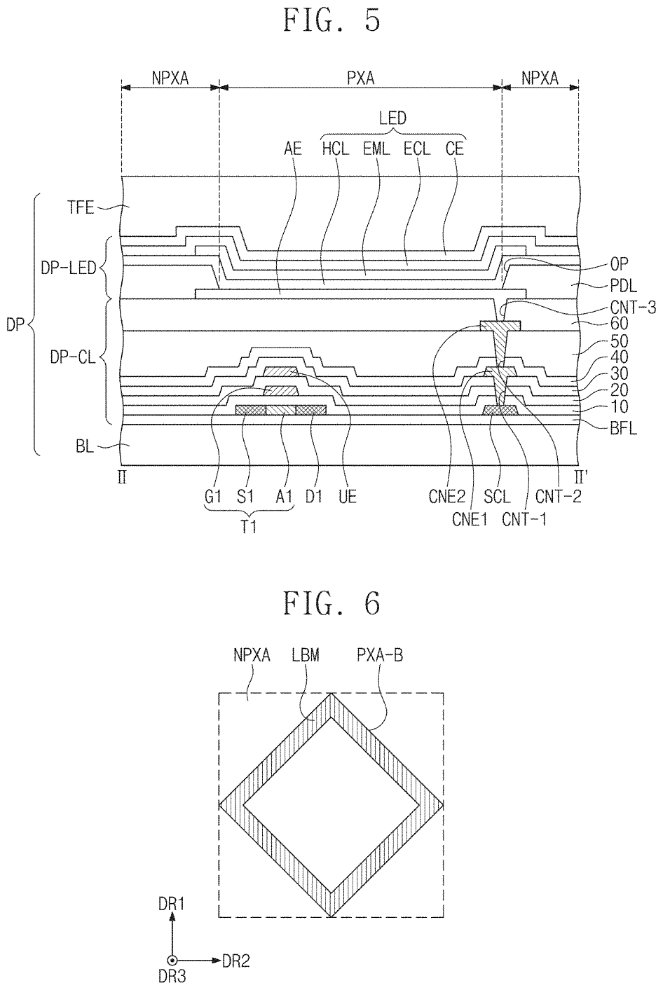

The pixels PX may be arranged in the active area AA. Each of the pixels PX may include a light emitting element (refer to FIG. 5) and a pixel driving circuit connected to the light emitting element. In an embodiment, the driving circuit GDC, the signal lines SGL, the pad part PLD, and the pixel driving circuit may be included in a display circuit layer DP-CL as shown in FIG. 5.

The driving circuit GDC may include a gate driving circuit. The gate driving circuit may generate a plurality of gate signals and may sequentially output the gate signals to a plurality of gate lines GL described later. The gate driving circuit may further output other control signals to the pixel driving circuit.

The signal lines SGL may include the gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be connected to the pixels PX. The control signal line CSL may provide control signals to the driving circuit GDC. The signal lines SGL may overlap the active area AA and the peripheral area NAA.

The pad part PLD may be connected to the flexible circuit board FCB (refer to FIG. 1B) and may include the pixel pads D-PD to connect the flexible circuit board FCB to the display panel DP and input pads I-PD to connect the flexible circuit board FCB to the input sensing unit ISP. The pixel pads D-PD and the input pads I-PD may be provided by exposing some of lines disposed on the display circuit layer DP-CL without being covered by an insulating layer included in the display circuit layer DP-CL.

The pixel pads D-PD may be connected to corresponding pixels PX via the signal lines SGL. In addition, the driving circuit GDC may be connected to one pixel pad among the pixel pads D-PD.

Referring to FIG. 3, in an embodiment, the input sensing unit ISP may include first sensing electrodes IE1-1, IE-1-2, IE-1-3, IE-1-4, and IE1-5, first signal lines SL1-1, SL1-2, SL1-3, SL1-4, and SL1-5 connected to the first sensing electrodes IE1-1, IE-1-2, IE-1-3, IE-1-4, and IE1-5, second sensing electrodes IE2-1, IE2-2, IE2-3, and IE2-4, and second signal lines SL2-1, SL2-2, SL2-3, and SL2-4 connected to the second sensing electrodes IE2-1, IE2-2, IE2-3, and IE2-4. According to an embodiment, the input sensing unit ISP may further include third signal lines connected to the second sensing electrodes IE2-1, IE2-2, IE2-3, and IE2-4. In such an embodiment, the second signal lines SL2-1, SL2-2, SL2-3, and SL2-4 may be connected to one ends of the second sensing electrodes IE2-1, IE2-2, IE2-3, and IE2-4, and the third signal lines may be connected to the other ends of the second sensing electrodes IE2-1, IE2-2, IE2-3, and IE2-4.

The first sensing electrodes IE1-1, IE-1-2, IE-1-3, IE-1-4, and IE1-5 may cross the second sensing electrodes IE2-1, IE2-2, IE2-3, and IE2-4. The first sensing electrodes IE1-1, IE-1-2, IE-1-3, IE-1-4, and IE1-5 may be arranged in the first direction DR1 and may extend in the second direction DR2.

Each of the first sensing electrodes IE1-1, IE-1-2, IE-1-3, IE-1-4, and IE1-5 may include first sensor portions SP1 and first connection portions CP1, which are arranged in the active area AA. Each of the second sensing electrodes IE2-1, IE2-2, IE2-3, and IE2-4 may include second sensor portions SP2 and second connection portions CP2, which are arranged in the active area AA. Among the first sensor portions SP1, two first sensor portions disposed at opposing ends of the first sensing electrode may have a size, e.g., a half size (½), smaller than that of the first sensor portion disposed at a center thereof. Among the second sensor portions SP2, two second sensor portions disposed at opposing ends of the second sensing electrode may have a size, e.g., a half size (½), smaller than that of the second sensor portion disposed at a center thereof.

FIG. 3 shows the first sensing electrodes IE1-1, IE-1-2, IE-1-3, IE-1-4, and IE1-5 and the second sensing electrodes IE2-1, IE2-2, IE2-3, and IE2-4 according to an embodiment, however, the shape of the first sensing electrodes IE1-1, IE-1-2, IE-1-3, IE-1-4, and IE1-5 and the second sensing electrodes IE2-1, IE2-2, IE2-3, and IE2-4 should not be limited thereto or thereby. According to an alternative embodiment, the first sensing electrodes IE1-1, IE-1-2, IE-1-3, IE-1-4, and IE1-5 and the second sensing electrodes IE2-1, IE2-2, IE2-3, and IE2-4 may have a bar shape in which the sensor portion and the connection portion are not distinguished from each other. In an embodiment, as shown in FIG. 3, the first sensor portions SP1 and the second sensor portions SP2 may have a lozenge shape, however, they should not be limited to the lozenge shape. Alternatively, the first sensor portions SP1 and the second sensor portions SP2 may have another polygonal shape.

In one first sensing electrode, the first sensor portions SP1 may be arranged in the second direction DR2, and in one second sensing electrode, the second sensor portions SP2 may be arranged in the first direction DR1. Each of the first connection portions CP1 may connect the first sensor portions SP1 adjacent to each other, and each of the second connection portions CP2 may connect the second sensor portions SP2 adjacent to each other.

In an embodiment, the first sensing electrodes IE1-1, IE-1-2, IE-1-3, IE-1-4, and IE1-5 and the second sensing electrodes IE2-1, IE2-2, IE2-3, and IE2-4 may have a mesh shape. In such an embodiment where the first sensing electrodes IE1-1, IE-1-2, IE-1-3, IE-1-4, and IE1-5 and the second sensing electrodes IE2-1, IE2-2, IE2-3, and IE2-4 have the mesh shape, a parasitic capacitance between the electrodes of the display panel DP (refer to FIG. 2) and the first sensing electrodes IE1-1, IE-1-2, IE-1-3, IE-1-4, and IE1-5 and the second sensing electrodes IE2-1, IE2-2, IE2-3, and IE2-4 may be reduced.

The first sensing electrodes IE1-1, IE-1-2, IE-1-3, IE-1-4, and IE1-5 and the second sensing electrodes IE2-1, IE2-2, IE2-3, and IE2-4, which have the mesh shape, may include silver, aluminum, copper, chromium, nickel, titanium, or the like, which may be processed at a low temperature, however, they should not be limited thereto or thereby. In such an embodiment, when the input sensing unit ISP is formed through successive processes, the light emitting elements LED (refer to FIG. 5) may be prevented from being damaged.

The first signal lines SL1-1, SL1-2, SL1-3, SL1-4, and SL1-5 may be respectively connected to one ends of the first sensing electrodes IE1-1, IE-1-2, IE-1-3, IE-1-4, and IE1-5. According to an embodiment, the input sensing unit ISP may further include the first signal lines connected to the other ends of the first sensing electrodes IE1-1, IE-1-2, IE-1-3, IE-1-4, and IE1-5.

The first signal lines SL1-1, SL1-2, SL1-3, SL1-4, and SL1-5 and the second signal lines SL2-1, SL2-2, SL2-3, and SL2-4 may be disposed in the peripheral area NAA. The input sensing unit ISP may include input pads I-PD extending from one ends of the first signal lines SL1-1, SL1-2, SL1-3, SL1-4, and SL1-5 and the second signal lines SL2-1, SL2-2, SL2-3, and SL2-4 and disposed in the peripheral area NAA.

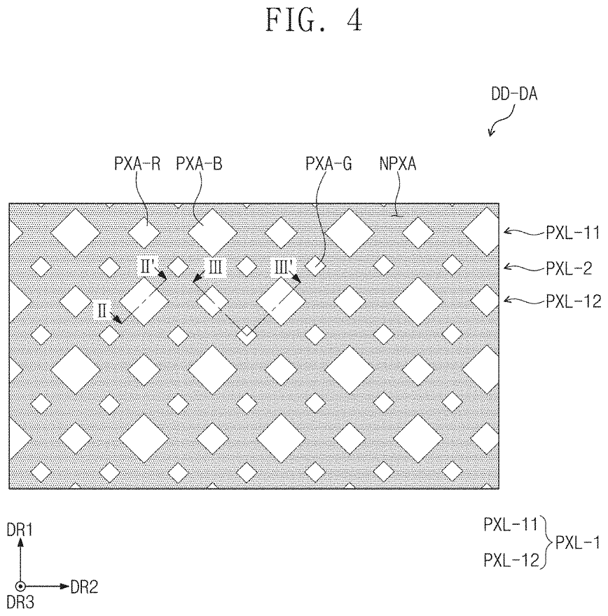

FIG. 4 is a plan view showing a display area DD-DA according to an embodiment of the disclosure. FIG. 4 shows an enlarged plan view of the display area DD-DA corresponding to a portion of the display panel DP shown in FIG. 2.

Referring to FIG. 4, in an embodiment, the display area DD-DA may include a plurality of light emitting areas PXA-B, PXA-G, and PXA-R defined therein. A peripheral area NPXA may be defined adjacent to the light emitting areas PXA-B, PXA-G, and PXA-R. The peripheral area NPXA may define a boundary between the light emitting areas PXA-B, PXA-G, and PXA-R and may prevent color mixing between the light emitting areas PXA-B, PXA-G, and PXA-R. The light emitting areas PXA-B, PXA-G, and PXA-R may define a plurality of pixel rows PXL-1 and PXL-2 extending in the second direction DR2. In FIG. 4, the second direction DR2 may be defined as an extension direction or a row direction of the pixel rows PXL-1 and PXL-2, and the first direction DR1 may be defined as a column direction.

In an embodiment, the pixel rows PXL-1 and PXL-2 may be grouped into two groups. The pixel rows PXL-1 of a first group may include first light emitting areas PXA-B that emit a first light and third light emitting areas PXA-R that emit a third light. The first light emitting areas PXA-B may be alternately arranged with the third light emitting areas PXA-R in the row direction DR2. The pixel rows PXL-1 of the first group may include a first pixel row PXL-11 and a second pixel row PXL-12. The first pixel rows PXL-11 and the second pixel rows PXL-12 may be alternately arranged with each other in the column direction DR1.

An arrangement order of the first light emitting areas PXA-B and the third light emitting areas PXA-R in the first pixel row PXL-11 may be different from that in the second pixel row PXL-12. In the column direction DR1, the first light emitting areas PXA-B of the first pixel row PXL-11 and the third light emitting areas PXA-R of the second pixel row PXL-12 may be arranged in the column direction DR1, and the third light emitting areas PXA-R of the first pixel row PXL-11 and the first light emitting areas PXA-B of the second pixel row PXL-12 may be arranged in the column direction DR1.

The pixel rows PXL-2 of a second group may include second light emitting areas PXA-G that emit a second light.

The pixel rows PXL-1 of the first group and the pixel rows PXL-2 of the second group may be alternately arranged with each other in the column direction DR1. The pixel row PXL-2 of the second group may be disposed between the first pixel row PXL-11 and the second pixel row PXL-12, which are successive to each other, and one of the first pixel row PXL-11 and the second pixel row PXL-12 may be disposed between the pixel rows PXL-2 adjacent to each other of the second group.

In an embodiment, as shown in FIG. 4, the first light emitting areas PXA-B, the second light emitting areas PXA-G, and the third light emitting areas PXA-R may have different sizes from each other when viewed in a plan view, however, they should not be limited thereto or thereby. In an embodiment, as shown in FIG. 4, among the light emitting areas, the size of the first light emitting areas PXA-B is largest, the size of the second light emitting areas PXA-G is smallest, for example. In an embodiment, the first light emitting areas PXA-B, the second light emitting areas PXA-G, and the third light emitting areas PXA-R may have a square shape, however, they should not be limited to the square shape. In one alternative embodiment, for example, at least one selected from the first light emitting areas PXA-B, the second light emitting areas PXA-G, and the third light emitting areas PXA-R may have a rectangular shape, a rectangular shape with rounded corners, or a square shape with rounded corners. Herein, the expression “when viewed in a plan view” may mean a state of being viewed in a direction perpendicular to the first direction DR1 and the second direction DR2, that is, the third direction DR3.

In an embodiment, the first light emitting areas PXA-B may emit a blue light, the second light emitting areas PXA-G may emit a green light, and the third light emitting areas PXA-R may emit a red light, however, they should not be limited thereto or thereby. The color lights emitted from the first light emitting areas PXA-B, the second light emitting areas PXA-G, and the third light emitting areas PXA-R may be selected as a combination of three color lights in which the emitted color lights may be mixed to generate a white light.

FIG. 5 is a cross-sectional view showing the display panel DP according to an embodiment of the disclosure. FIG. 5 shows a cross-section taken along line II-II′ of FIG. 4. FIG. 5 shows an embodiment of the display panel DP described above with reference to FIGS. 1A to 1C.

Referring to FIG. 5, an embodiment of the display panel DP may include a base layer BL, the display circuit layer DP-CL, a display element layer DP-LED, and an encapsulation layer TFE. A stack structure of the display panel DP should not be particularly limited.

The display panel DP may include a plurality of insulating layers, a semiconductor pattern, a conductive pattern, and a signal line. In an embodiment, an insulating layer, a semiconductor layer, and a conductive layer may be formed by a coating or depositing process. Then, the insulating layer, the semiconductor layer, and the conductive layer may be selectively patterned by a photolithography process. Accordingly, the semiconductor pattern, the conductive pattern, and the signal line included in the display circuit layer DP-CL and the display element layer DP-LED may be formed.

The base layer BL may include a synthetic resin film. The base layer BL may include a glass substrate, a metal substrate, or an organic/inorganic composite substrate.

At least one inorganic layer may be disposed or formed on an upper surface of the base layer BL. The buffer layer BFL may increase an adhesive force between the base layer BL and the semiconductor pattern. The buffer layer BFL may include a silicon oxide layer and a silicon nitride layer, and the silicon oxide layer and the silicon nitride layer may be alternately stacked with each other.

The semiconductor pattern may be disposed on the buffer layer BFL. The semiconductor pattern may include polysilicon, however, it should not be limited thereto or thereby. The semiconductor pattern may include amorphous silicon or metal oxide.

FIG. 5 shows only a portion of the semiconductor pattern, and the semiconductor pattern may be further disposed in the light emitting areas PXA-B, PXA-G, and PXA-R (refer to FIG. 4). The semiconductor pattern may be arranged with a predetermined pattern over the light emitting areas PXA-B, PXA-G, and PXA-R. The semiconductor pattern may have different electrical properties depending on whether it is doped or not and whether it is doped with an N-type dopant or a P-type dopant. The semiconductor pattern may include a doped region and a non-doped region. The doped region may be doped with the N-type dopant or the P-type dopant. A P-type transistor may include a doped region doped with the P-type dopant.

The doped region may have a conductivity greater than that of the non-doped region and may substantially serve as an electrode or signal line. The non-doped region may substantially correspond to an active area (or a channel area) of a transistor. In an embodiment, a portion of the semiconductor pattern may be the active area of the transistor, another portion of the semiconductor pattern may be a source or a drain of the transistor, and the other portion of the semiconductor pattern may be a connection electrode or a connection signal line.

In an embodiment, as shown in FIG. 5, a source S1, an active area (hereinafter, will be reference to as “active”) A1, and a drain D1 of a transistor T1 may be formed from (or defined by portions of) the semiconductor pattern. FIG. 5 shows a portion of a connection signal line SCL formed from the semiconductor pattern. Although not shown in figures, the connection signal line SCL may be connected to the drain D1 of the transistor T1 in a plane.

First, second, third, fourth, fifth, and sixth insulating layers 10, 20, 30, 40, 50, and 60 may be disposed on the buffer layer BFL. Each of the first to sixth insulating layers 10 to 60 may be an inorganic layer or an organic layer. A gate G1 may be disposed on the first insulating layer 10. An upper electrode UE may be disposed on the second insulating layer 20. A first connection electrode CNE1 may be disposed on the third insulating layer 30. The first connection electrode CNE1 may be connected to the connection signal line SCL via a first contact hole CNT-1 defined through the first, second, and third insulating layers 10, 20, and 30. A second connection electrode CNE2 may be disposed on the fifth insulating layer 50. The second connection electrode CNE2 may be connected to the first connection electrode CNE1 via a contact hole CNT-2 defined through the fourth insulating layer 40 and the fifth insulating layer 50.

The light emitting element LED may be disposed on the sixth insulating layer 60. A first electrode AE may be disposed on the sixth insulating layer 60. The first electrode AE may be connected to the second connection electrode CNE2 via a contact hole CNT-3 defined through the sixth insulating layer 60. A pixel definition layer PDL may be provided with an opening OP (hereinafter, referred to as a light emitting opening). At least a portion of the first electrode AE may be exposed through the light emitting opening OP.

According to an embodiment, the pixel definition layer PDL may have a black color. The pixel definition layer PDL may include a black coloring agent. The pixel definition layer PDL may include a black pigment or a black dye, which is mixed with a base resin.

FIG. 5 shows the first light emitting areas PXA-B and the peripheral area NPXA (or non-light-emitting areas) adjacent to the first light emitting areas PXA-B. In an embodiment, the light emitting areas PXA-B, PXA-G, and PXA-R may be defined to correspond some areas of the first electrode AE exposed through the light emitting opening OP.

A hole control layer HCL may be commonly disposed in the light emitting areas PXA and the peripheral area NPXA. The hole control layer HCL may include a hole transport layer and may further include a hole injection layer. A light emitting layer EML may be disposed on the hole control layer HCL. The light emitting layer EML may be disposed in an area corresponding to the light emitting opening OP. In such an embodiment, the light emitting layer EML may be disposed in each of the light emitting areas PXA-B, PXA-G, and PXA-R after being divided into portions.

An electron control layer ECL may be disposed on the light emitting layer EML. The electron control layer ECL may include an electron transport layer and may further include an electron injection layer. A second electrode CE may be disposed on the electron control layer ECL.

An encapsulation layer TFE may be disposed on the second electrode CE. The encapsulation layer TFE may include a plurality of thin layers. Although not shown in figures, a capping layer may be disposed between the encapsulation layer TFE and the display element layer DP-LED.

FIG. 6 is a plan views showing a portion of the display device according to an embodiment of the disclosure. FIG. 6 is an enlarged view showing one first light emitting area PXA-B of the display area DD-DA and the peripheral area NPXA adjacent to the light emitting area PXA-B.

Referring to FIG. 6, a light blocking member LBM may be disposed in the first light emitting area PXA-B. At least a portion of the light blocking member LBM may be disposed on the first light emitting area PXA-B. The light blocking member LBM may be disposed to overlap a portion of the first light emitting area PXA-B. The light blocking member LBM may be disposed at a boundary of the first light emitting area PXA-B. An end of the light blocking member LBM may be disposed to be aligned with the boundary between the first light emitting area PXA-B and the peripheral area NPXA. Herein, the expression “components are substantially aligned with each other” not only means a case that a position of one component completely coincides with a position the other component on a plane but also means a case that one component coincides with the other component within a range including differences that may occur due to fabrication errors in spite of the same design.

According to an embodiment, the display device may include a light blocking member disposed to overlap the portion of the light emitting area. Accordingly, although a brightness of a front view decreases, a brightness of a side view may increase. Thus, when compared with the brightness retention rate in the front surface, the brightness retention rate in the side surface may be improved compared with that in the front surface. Hereinafter, the light blocking member included in the display device will be described in detail.

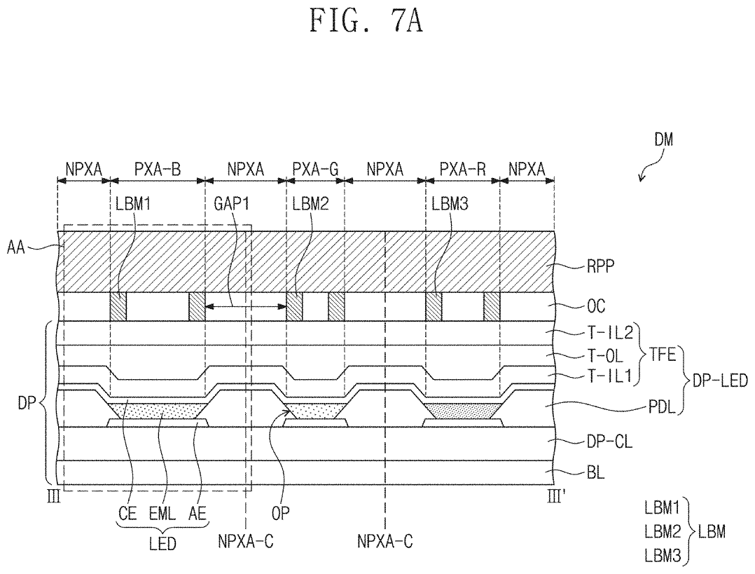

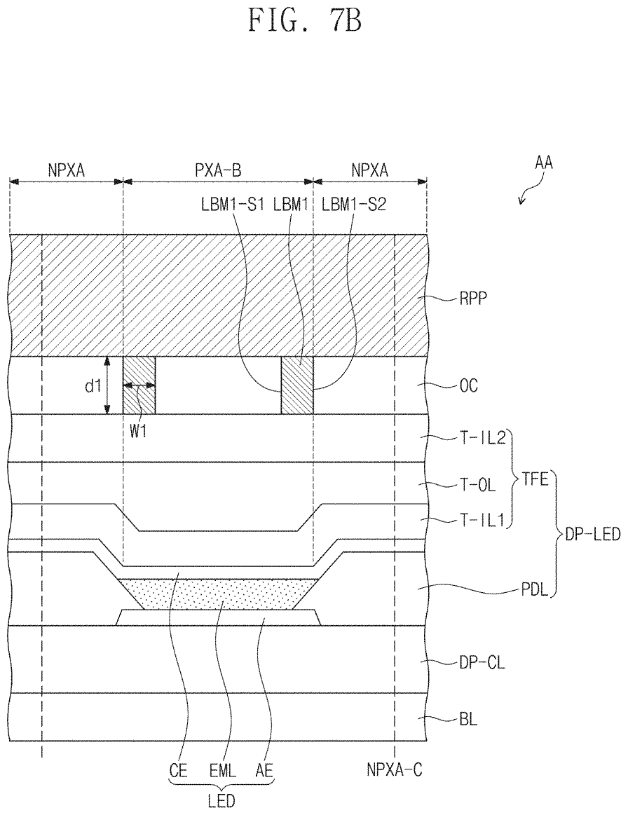

FIG. 7A is a cross-sectional view showing a display module DM according to an embodiment of the disclosure, and FIG. 7B is an enlarged plan view showing the display module DM according to an embodiment of the disclosure. FIG. 7A is a cross-sectional view taken along line of FIG. 4. FIG. 7B is an enlarged view showing an area AA of FIG. 7A.

Referring to FIGS. 7A and 7B, an embodiment of the display panel DP of the display module DM may include the base layer BL, the display circuit layer DP-CL, the display element layer DP-LED, and the encapsulation layer TFE. The display circuit layer DP-CL, the display element layer DP-LED, and the encapsulation layer TFE may be disposed on the base layer BL. Although not shown in figures, the display panel DP may further include functional layers, such as an anti-reflective layer, a refractive index control layer, and the like.

The base layer BL may include a synthetic resin layer. The synthetic resin layer is formed on a work substrate used when the display panel DP is manufactured. Then, a conductive layer and an insulating layer are formed on the synthetic resin layer. When the work substrate is removed, the synthetic resin layer corresponds to the base layer BL. The synthetic resin layer may be a polyimide-based resin layer, however, a material for the synthetic resin layer should not be particularly limited. In an embodiment, the base layer BL may include a glass substrate, a metal substrate, or an organic/inorganic composite substrate.

The display circuit layer DP-CL may include at least one insulating layer and a circuit element. Hereinafter, the insulating layer included in the display circuit layer DP-CL will be referred to as an “interlayer insulating layer”. The interlayer insulating layer may include at least one intermediate inorganic layer and at least one intermediate organic layer. The circuit element may include a signal line and a pixel driving circuit. The display circuit layer DP-CL may be formed through a process of forming an insulating layer, a semiconductor layer, and a conductive layer using coating and depositing processes and a process of patterning the insulating layer, the semiconductor layer, and the conductive layer using a photolithography process.

In an embodiment, the display element layer DP-LED may include a pixel definition layer PDL and the light emitting element LED. The pixel definition layer PDL may include an organic material. The first electrode AE may be disposed on the display circuit layer DP-CL. The pixel definition layer PDL may be formed on the first electrode AE. The opening OP may be defined through the pixel definition layer PDL. At least the portion of the first electrode AE may be exposed through the opening OP of the pixel definition layer PDL. According to an alternative embodiment, the pixel definition layer PDL may be omitted.

In an embodiment, as shown in FIG. 7A, the display panel DP may include the light emitting areas PXA-B, PXA-G, and PXA-R and the non-light-emitting area NPXA adjacent to the light emitting areas PXA-B, PXA-G, and PXA-R. In such an embodiment, the light emitting areas PXA-B, PXA-G, and PXA-R may be defined to correspond to the light emitting layer EML disposed in the opening OP. The first electrode AE may be divided into portions, and the portions of the first electrode AE may be respectively disposed or formed in the light emitting areas PXA-B, PXA-G, and PXA-R.

The light emitting layer EML that emits the light may be disposed on the first electrode AE. The light emitting layer EML may be disposed in an area corresponding to the opening OP. In an embodiment, the light emitting layer EML may be respectively formed in the light emitting areas PXA-B, PXA-G, and PXA-R after being divided into a plurality of portions. The light emitting layer EML may include an organic material and/or an inorganic material. The light emitting layer EML may generate a predetermined color light. In one embodiment, for example, the light emitting layer EML may generate one of a red light, a green light, and a blue light.

In an embodiment, the light emitting layer EML may be the patterned layer, however, alternatively, the light emitting layer EML may be commonly disposed in the light emitting areas PXA-B, PXA-G, and PXA-R. In such an embodiment, the light emitting layer EML may generate a white light. In an embodiment, the light emitting layer EML may have a multi-layer structure, e.g., a tandem structure.

Although not shown in FIGS. 7A and 7B, the hole control layer HCL (refer to FIG. 5) may be disposed between the light emitting layer EML and the first electrode AE. The hole control layer HCL may be commonly disposed in the light emitting areas PXA-B, PXA-G, and PXA-R and the peripheral area NPXA.

The second electrode CE may be disposed on the light emitting layer EML. The second electrode CE may be commonly disposed in the light emitting areas PXA-B, PXA-G, and PXA-R and the peripheral area NPXA.

Although not shown in FIGS. 7A and 7B, the electron control layer ECL (refer to FIG. 5) may be disposed between the light emitting layer EML and the second electrode CE. The electron control layer ECL may be commonly disposed in the light emitting areas PXA-B, PXA-G, and PXA-R and the peripheral area NPXA.

The encapsulation layer TFE may be disposed on the second electrode CE. The encapsulation layer TFE may encapsulate the display element layer DP-LED. The encapsulation layer TFE may include at least one insulating layer. According to an embodiment, the encapsulation layer TFE may include at least inorganic layer (hereinafter, referred to as a first encapsulation inorganic layer T-IL1). According to an embodiment, the encapsulation layer TFE may include at least one organic layer (hereinafter, referred to as an encapsulation organic layer T-OL) and at least one inorganic layer (hereinafter, referred to as a second encapsulation inorganic layer T-IL2). The encapsulation organic layer T-OL may be disposed between the first encapsulation inorganic layer T-IL1 and the second encapsulation inorganic layer T-IL2.

The first encapsulation inorganic layer T-IL1 and the second encapsulation inorganic layer T-IL2 may prevent the display element layer DP-LED from moisture and oxygen, and the encapsulation organic layer T-OL may prevent the display element layer DP-LED from a foreign substance such as dust particles. The first and second encapsulation inorganic layers T-IL1 and T-IL2 may include a silicon nitride layer, a silicon oxynitride layer, a silicon oxide layer, a titanium oxide layer, or an aluminum oxide layer, however, they should not be particularly limited. The encapsulation organic layer T-OL may include an acrylic-based organic layer, however, it should not be limited thereto or thereby.

The light blocking member LBM may be disposed on the encapsulation layer TFE. The light blocking member LBM may be disposed between the anti-reflective unit RPP and the display element layer DP-LED. An overcoat layer OC may be disposed on a layer on which the light blocking member LBM is disposed to protect the light blocking member LBM and to planarize an upper portion of the light blocking member LBM. The overcoat layer OC may include an organic material and may provide a flat surface on the layer on which the light blocking member LBM is disposed. FIGS. 7A and 7B show an embodiment having a structure in which the overcoat layer OC covers side surfaces of the light blocking member LBM, however, the disclosure should not be limited thereto or thereby. According to an alternative embodiment, the overcoat layer OC may also cover an upper surface of the light blocking member LBM. According to another alternative embodiment, the overcoat layer OC may be omitted.

The light blocking member LBM may be a pattern with a black color, e.g., a black matrix. According to an embodiment, the light blocking member LBM may include a black coloring agent. The black coloring agent may include a black pigment and/or a black dye. The black coloring agent may include a metal such as carbon black or chromium, or an oxide thereof.

At least a portion of the light blocking member LBM may be disposed in each of the light emitting areas PXA-B, PXA-G, and PXA-R. In an embodiment, as shown in FIGS. 7A and 7B, the light blocking member LBM may be disposed in the light emitting areas PXA-B, PXA-G, and PXA-R and may not be disposed in the peripheral area NPXA. In such an embodiment, the light blocking member LBM may not overlap the peripheral area NPXA, however, it should not be limited thereto or thereby. According to an alternative embodiment, a portion of the light blocking member LBM may be disposed in the peripheral area NPXA.

The light blocking member LBM may include a first sub-light blocking member LBM1 disposed in the first light emitting areas PXA-B, a second sub-light blocking member LBM2 disposed in the second light emitting areas PXA-G, and a third sub-light blocking member LBM3 disposed in the third light emitting areas PXA-R.

One side surface of the light blocking member LBM may be disposed in the light emitting areas PXA-B, PXA-G, and PXA-R. According to an embodiment, the first sub-light blocking member LBM1 disposed in the first light emitting areas PXA-B may include a first side surface LBM1-S1 and a second side surface LBM1-S2, and the first side surface LBM1-S1 may be disposed in the first light emitting areas PXA-B. The first side surface LBM1-S1 may be an inner side surface disposed closer to a center portion of the first light emitting areas PXA-B to which the first side surface LBM1-S1 than the second side surface LBM1-S2 is. In such an embodiment, the second sub-light blocking member LBM2 and the third sub-light blocking member LBM3 may include inner side surfaces respectively disposed in the second light emitting areas PXA-G and the third light emitting areas PXA-R.

The other side surface of the light blocking member LBM, which is opposite to the one side surface of the light blocking member LBM, may be disposed closer to a center of the peripheral area NPXA than the one side surface of the light blocking member LBM is. According to an embodiment, the second side surface LBM1-S2 of the first sub-light blocking member LBM1 may be disposed closer to an imaginary center line NPXA-C crossing the center of the peripheral area NPXA than the first side surface LBM1-S1 is. Although not shown in figures, the other side surface of each of the second sub-light blocking member LBM2 and the third sub-light blocking member LBM3 may also be disposed closer to the center of the peripheral area NPXA than the inner side surfaces respectively disposed in the second light emitting areas PXA-G and the third light emitting areas PXA-R are.

The other side surface of the light blocking member LBM may be substantially disposed at a boundary between the light emitting areas PXA-B, PXA-G, and PXA-R and the peripheral area NPXA. As shown in FIGS. 7A and 7B, the second side surface LBM1-S2 of the first sub-light blocking member LBM1 may be disposed at the boundary between the first light emitting areas PXA-B and the peripheral area NPXA. As shown in FIG. 7A, the other side surface of the second sub-light blocking member LBM2 may be disposed at the boundary between the second light emitting areas PXA-G and the peripheral area NPXA, and the other side surface of the third sub-light blocking member LBM3 may be disposed at the boundary between the third light emitting areas PXA-R and the peripheral area NPXA. In such an embodiment, the other side surface of the light blocking member LBM may be slightly displaced from the boundary between the light emitting areas PXA-B, PXA-G, and PXA-R and the peripheral area NPXA due to process errors. According to an embodiment, the other side surface of the light blocking member LBM may be disposed at a distance of about 0.5 micrometers or less from the boundary between the light emitting areas PXA-B, PXA-G, and PXA-R and the peripheral area NPXA. In such an embodiment, the other side surface of the light blocking member LBM may be shifted from the boundary between the light emitting areas PXA-B, PXA-G, and PXA-R and the peripheral area NPXA by about 0.5 micrometers or less toward the light emitting areas PXA-B, PXA-G, and PXA-R, or may be shifted from the boundary between the light emitting areas PXA-B, PXA-G, and PXA-R and the peripheral area NPXA by about 0.5 micrometers or less toward the peripheral area NPXA.

A predetermined gap may be defined between the light blocking members LBM disposed in different light emitting areas among the light emitting areas PXA-B, PXA-G, and PXA-R. According to an embodiment, a first gap GAP1 may be defined between the first sub-light blocking member LBM1 and the second sub-light blocking member LBM2. A separate light blocking material pattern may not be disposed in the first gap GAP1. In such an embodiment, a gap in which the light blocking material pattern is not disposed may be defined between the light blocking members LBM disposed in different light emitting areas.

According to an embodiment, the light blocking member LBM may have a width W1 equal to or greater than about 0.5 micrometers and equal to or smaller than about 3 micrometers. In a case where the width W1 of the light blocking member LBM is smaller than about 0.5 micrometers, a desired light blocking effect may not be achieved. In a case where the width W1 of the light blocking member LBM is greater than about 3 micrometers, the front surfaces of the light emitting areas PXA-B, PXA-G, and PXA-R may be excessively blocked by the light blocking member LBM, and as a result, a display efficiency in the front surface may be deteriorated. FIG. 7A shows an embodiment having a structure in which the first sub-light blocking member LBM1, the second sub-light blocking member LBM2, and the third sub-light blocking member LBM3 have substantially the same width as each other, however, the structure should not be limited thereto or thereby. According to an alternative embodiment, the first sub-light blocking member LBM1, the second sub-light blocking member LBM2, and the third sub-light blocking member LBM3 may have different widths from each other. In one embodiment, for example, when viewed in a plan view, the widths of the first sub-light blocking member LBM1, the second sub-light blocking member LBM2, and the third sub-light blocking member LBM3 may be determined proportional to sizes of the first light emitting areas PXA-B, the second light emitting areas PXA-G, and the third light emitting areas PXA-R, respectively.

According to an embodiment, the light blocking member LBM may have a thickness dl equal to or greater than about 0.5 micrometers and equal to or smaller than about 2 micrometers. In a case where the thickness dl of the light blocking member LBM is smaller than about 0.5 micrometers, a desired light blocking effect may not be achieved. In a case where the thickness dl of the light blocking member LBM is greater than about 2 micrometers, a brightness in a side view of the light emitting areas PXA-B, PXA-G, and PXA-R may be excessively deteriorated by the light blocking member LBM, and thus, a display efficiency in the side surface may be deteriorated. FIG. 7A shows an embodiment having a structure in which the first sub-light blocking member LBM1, the second sub-light blocking member LBM2, and the third sub-light blocking member LBM3 have substantially the same thickness as each other, however, the structure should not be limited thereto or thereby. According to an alternative embodiment, the first sub-light blocking member LBM1, the second sub-light blocking member LBM2, and the third sub-light blocking member LBM3 may have different thicknesses from each other.

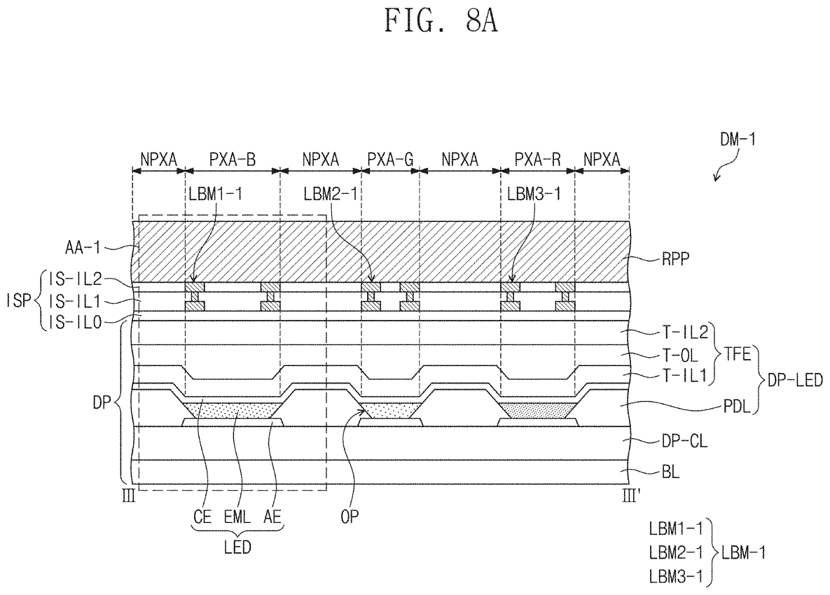

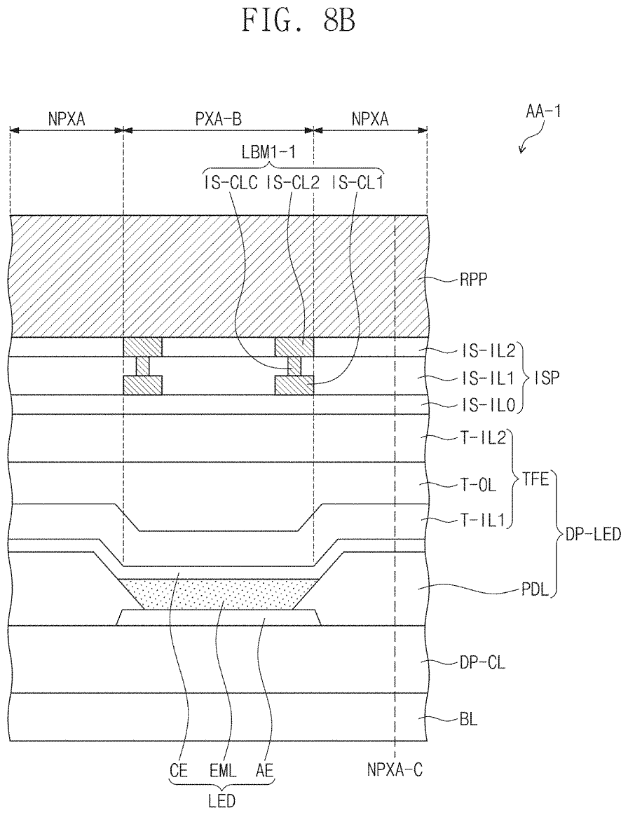

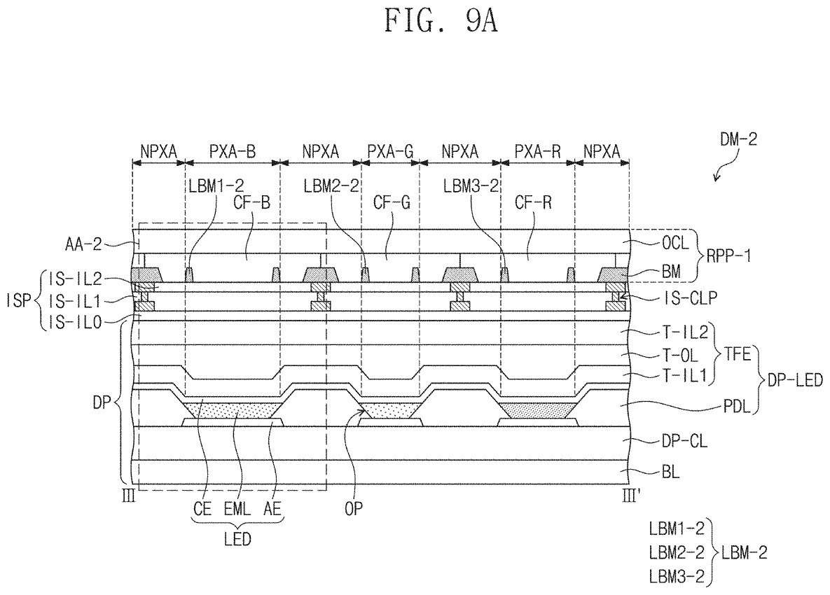

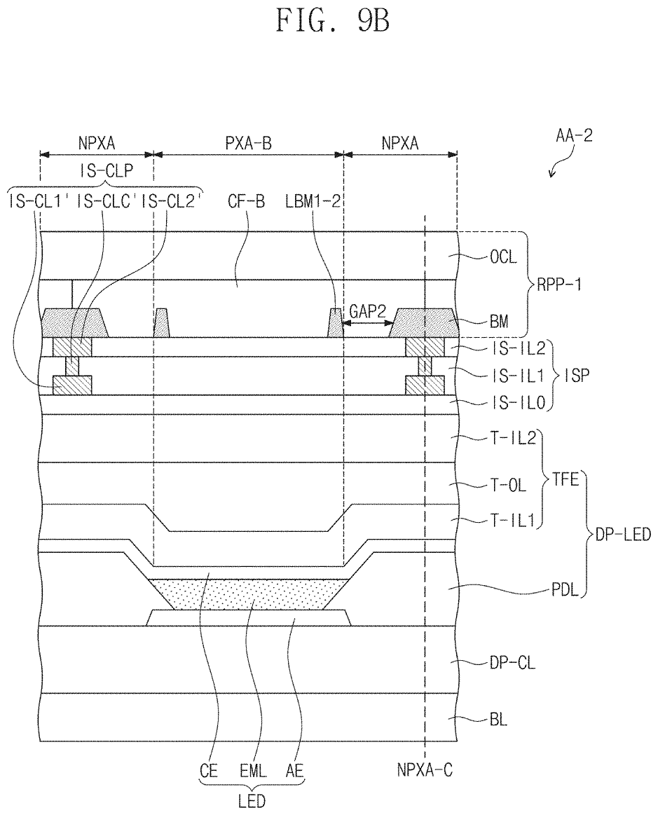

FIGS. 8A and 9A are cross-sectional views showing display modules DM-1 and DM-2 according to alternative embodiments of the disclosure, and FIGS. 8B and 9B are cross-sectional views showing a portion of the display modules DM-1 and DM-2 according to alternative embodiments of the disclosure. FIGS. 8A and 9A are cross-sectional views taken along line of FIG. 4. FIG. 8B is an enlarged view showing an area AA-1 of FIG. 8A, and FIG. 9B is an enlarged view showing an area AA-2 of FIG. 9A. In FIGS. 8A, 8B, 9A, and 9B, the same reference numerals denote the same elements as those in FIGS. 7A and 7B, and thus, any repetitive detailed descriptions thereof will be omitted or simplified. Referring to FIGS. 8A and 8B, in an embodiment, an input sensing unit ISP may be disposed on a display panel DP, and an anti-reflective unit RPP may be disposed on the input sensing unit ISP. The input sensing unit ISP may be disposed directly on an encapsulation layer TFE of the display panel DP. The anti-reflective unit RPP may be disposed directly on a second insulating layer IS-IL2 of the input sensing unit ISP. The light blocking member LBM-1 may be disposed on the input sensing unit ISP.

The input sensing unit ISP may include a plurality of insulating layers and a plurality of conductive layers, and the light blocking member LBM-1 may include some of the conductive layers included in the input sensing unit ISP.

The input sensing unit ISP may include a basic insulating layer IS-IL0, a first conductive layer IS-CL1 disposed on the basic insulating layer IS-IL0, a first insulating layer IS-IL1 covering the first conductive layer IS-CL1, a second conductive layer IS-CL2 disposed on the first insulating layer IS-IL1, and a second insulating layer IS-IL2 covering the second conductive layer IS-CL2. The first conductive layer IS-CL1 and the second conductive layer IS-CL2 may be electrically connected to each other via a connection conductive layer IS-CLC. In one embodiment, for example, the connection conductive layer IS-CLC may be integrally formed with the second conductive layer IS-CL2 as a single unitary unit. According to an alternative embodiment, the connection conductive layer IS-CLC may be omitted.

The basic insulating layer IS-IL0 may include an inorganic material. In one embodiment, for example, the basic insulating layer IS-IL0 may include a silicon nitride layer, a silicon oxide layer, or a silicon oxynitride layer. In an embodiment, a layer disposed at an uppermost position of the encapsulation layer TFE, for example, a second encapsulation inorganic layer T-IL2, may include a silicon nitride layer, a silicon oxide layer, or a silicon oxynitride layer. The silicon nitride layer, the silicon oxide layer, or the silicon oxynitride layer of the encapsulation layer TFE and the basic insulating layer IS-IL0 may be deposited under different conditions. According to an alternative embodiment, the basic insulating layer IS-IL0 may be omitted.

Each of the first insulating layer IS-IL1 and the second insulating layer IS-IL2 may include an inorganic layer or an organic layer. In one embodiment, for example, the first insulating layer IS-IL1 may include the inorganic layer, and the second insulating layer IS-IL2 may include the organic layer. According to an embodiment, the second insulating layer IS-IL2 may be omitted.

Each of the first conductive layer IS-CL1 and the second conductive layer IS-CL2 may have a single-layer structure or a multi-layer structure of layers stacked in the thickness direction. The conductive layer having the multi-layer structure may include two or more of transparent conductive layers and metal layers. The conductive layer having the multi-layer structure may include metal layers including different metals from each other. The transparent conductive layer may include indium tin oxide (“ITO”), indium zinc oxide (“IZO”), zinc oxide (ZnO), indium zinc tin oxide (“IZTO”), poly(3,4-ethylenedioxythiophene) (“PEDOT”), a metal nanowire, a graphene, or the like. The metal layer may include molybdenum, silver, titanium, copper, aluminum, or alloys thereof. In one embodiment, for example, each of the first conductive layer IS-CL1 and the second conductive layer IS-CL2 may have a three-metal-layer structure, i.e., a three-layer structure of titanium/aluminum/titanium. A metal with a relatively high durability and a low reflectance may be applied as or included in upper and lower layers, and a metal with a high electrical conductivity may be applied as or included in an inner layer.

Each of the first conductive layer IS-CL1 and the second conductive layer IS-CL2 may include a plurality of conductive patterns. According to an embodiment, the light blocking member LBM-1 may include a plurality of conductive patterns included in each of the first conductive layer IS-CL1 and the second conductive layer IS-CL2. In such an embodiment, each of the first conductive layer IS-CL1 and the second conductive layer IS-CL2 may include the conductive patterns disposed in each of light emitting areas PXA-B, PXA-G, and PXA-R, and each of the conductive patterns disposed in each of the light emitting areas PXA-B, PXA-G, and PXA-R may define the light blocking member LBM-1. The light blocking member LBM-1 may include a first sub-light blocking member LBM1-1 disposed in the first light emitting areas PXA-B, a second sub-light blocking member LBM2-1 disposed in the second light emitting areas PXA-G, and a third sub-light blocking member LBM3-1 disposed in the third light emitting areas PXA-R, and each of the first sub-light blocking member LBM1-1, the second sub-light blocking member LBM2-1, and the third sub-light blocking member LBM3-1 may include the conductive patterns disposed in each of the first conductive layer IS-CL1 and the second conductive layer IS-CL2.

At least some of the conductive patterns may have a black color to allow the conductive patterns included in the light blocking member LBM-1 to perform a light blocking function. According to an embodiment, an upper surface of an uppermost layer of the conductive layers included in the input sensing unit ISP may be blackened. In such an embodiment, an upper surface of the second conductive layer IS-CL2 may be blackened. In an embodiment, a titanium-bismuth (Ti—Bi) alloy thin film or an inorganic thin film may be disposed on the upper surface of the second conductive layer IS-CL2 and may be blackened.

Referring to FIGS. 9A and 9B, in an alternative embodiment, an input sensing unit ISP may be disposed on a display panel DP, and an anti-reflective unit RPP-1 may be disposed on the input sensing unit ISP. The input sensing unit ISP may be disposed directly on an encapsulation layer TFE of the display panel DP. The anti-reflective unit RPP-1 may be disposed directly on a second insulating layer IS-IL2 of the input sensing unit ISP. The light blocking member LBM-1 may be disposed on the anti-reflective unit RPP-1.

In an embodiment, as shown in FIGS. 9A and 9B, a sensing pattern IS-CLP disposed on the input sensing unit ISP may include a plurality of conductive layers and may be disposed to overlap an additional light blocking member BM. The additional light blocking member BM may prevent an external light from being reflected by the sensing pattern IS-CLP. The sensing pattern IS-CLP may include a first conductive layer IS-CL1′ and a second conductive layer IS-CL2′, and the first conductive layer IS-CL1′ and the second conductive layer IS-CL2′ may be electrically connected to each other via a connection conductive layer IS-CLC′. The connection conductive layer IS-CLC′ may be provided integrally with the second conductive layer IS-CL2′. According to an alternative embodiment, the connection conductive layer IS-CLC′ may be omitted.

The anti-reflective unit RPP-1 may be disposed directly on the input sensing unit ISP and may include a plurality of color filters. The color filters may include a first color filter CF-B, a second color filter CF-G, and a third color filter CF-R. The first color filter CF-B may correspond to a first light emitting areas PXA-B, the second color filter CF-G may correspond to a second light emitting areas PXA-G, and a third color filter CF-R may correspond to a third light emitting areas PXA-R. The first color filter CF-B may transmit a first light, i.e., a blue light, the second color filter CF-G may transmit a second light, i.e., a green light, and the third color filter CF-R may transmit a third light, i.e., a red light.

The first color filter CF-B, the second color filter CF-G, and the third color filter CF-R may reduce a reflectance of the external light. Since each of the first color filter CF-B, the second color filter CF-G, and the third color filter CF-R transmits a light in a specific wavelength range and absorbs a light in a wavelength range other than the specific wavelength range, the first color filter CF-B, the second color filter CF-G, and the third color filter CF-R may absorb most of a natural light incident thereto from the outside and may reflect only some of the natural light.

The first color filter CF-B, the second color filter CF-G, and the third color filter CF-R may include a base resin and a dye and/or a pigment distributed in the base resin. The base resin may be a medium in which the dye and/or the pigment are/is distributed and may include various resin compositions that are generally referred to as a binder.

The anti-reflective unit RPP-1 may include a protective layer OCL covering the first color filter CF-B, the second color filter CF-G, and the third color filter CF-R. The protective layer OCL may include an organic material and may provide a flat surface. According to an alternative embodiment, the protective layer OCL may be omitted.

According to an embodiment, a light blocking member LBM-2 may be disposed in the anti-reflective unit RPP-1. The light blocking member LBM-2 may be disposed in each of the first color filter CF-B, the second color filter CF-G, and the third color filter CF-R. The light blocking member LBM-2 may include a first sub-light blocking member LBM1-2 disposed in the first color filter CF-B and disposed in the first light emitting areas PXA-B, a second sub-light blocking member LBM2-2 disposed in the second color filter CF-G and disposed in the second light emitting areas PXA-G, and a third sub-light blocking member LBM3-2 disposed in the third color filter CF-R and disposed in the third light emitting areas PXA-R.

The light blocking member LBM-2 may be a pattern with a black color, e.g., a black matrix. According to an embodiment, the light blocking member LBM-2 may include a black coloring agent. The black coloring agent may include a black pigment and/or a black dye. The black coloring agent may include a metal such as carbon black or chromium, or an oxide thereof.

According to an embodiment, the light blocking member LBM-2 may be formed by stacking at least one selected from the first color filter CF-B, the second color filter CF-G, and the third color filter CF-R. According to an embodiment, the light blocking member LBM-2 may include a color filter having a color different from a color filter in which the light blocking member LBM-2 is disposed. According to an embodiment, the first sub-light blocking member LBM1-2 disposed in the first color filter CF-B may include a material having a color different from that of the first color filter CF-B. In one embodiment, for example, the first sub-light blocking member LBM1-2 may include a material included in the second color filter CF-G and/or the third color filter CF-R. In such an embodiment, the second sub-light blocking member LBM2-2 disposed in the second color filter CF-G may include a material having a color different from that of the second color filter CF-G. In one embodiment, for example, the second sub-light blocking member LBM2-2 may include a material included in the first color filter CF-B and/or the third color filter CF-R. In such an embodiment, the third sub-light blocking member LBM3-2 disposed in the third color filter CF-R may include a material having a color different from that of the third color filter CF-R. In one embodiment, for example, the third sub-light blocking member LBM3-2 may include a material included in the first color filter CF-B and/or the second color filter CF-G.

The anti-reflective unit RPP-1 may further include an additional light blocking member BM. The additional light blocking member BM may be disposed in a peripheral area NPXA and may not overlap the light emitting areas PXA-B, PXA-G, and PXA-R. The additional light blocking member BM may be a black matrix. The additional light blocking member BM may include an organic light blocking material or an inorganic light blocking material, which includes a black pigment or a black dye. The additional light blocking member BM may prevent a light leakage from occurring and may provide a boundary between the color filters CF-B, CF-G, and CF-R adjacent to each other. In an embodiment, the additional light blocking member BM may be formed by a blue filter. The additional light blocking member BM may be provided in plural, and the additional light blocking members BM may overlap a plurality of barrier walls BK, respectively. Although not shown in figures, the additional light blocking member BM may be formed by stacking at least one selected from the first color filter CF-B, the second color filter CF-G, and the third color filter CF-R. In one embodiment, for example, the additional light blocking member BM may be formed by stacking all the first color filter CF-B, the second color filter CF-G, and third color filter CF-R. In a case where the additional light blocking member BM is formed by stacking the first color filter CF-B, the second color filter CF-G, and the third color filter CF-R, a stacking order of the first color filter CF-B, the second color filter CF-G, and the third color filter CF-R should not be particularly limited.

The additional light blocking member BM and the light blocking member LBM-2 may be spaced apart from each other by a predetermined gap defined therebetween when viewed in a plane. As shown in FIG. 9B, the first sub-light blocking member LBM1-2 and the additional light blocking member BM may be spaced apart from each other by a second gap GAP2 defined therebetween. Although not shown in detail, each of the second sub-light blocking member LBM2-2 and the third sub-light blocking member LBM3-2 may be spaced apart from the additional light blocking member BM by the second gap GAP2 defined therebetween when viewed in a plan view. A separate light blocking material pattern may not be disposed in the second gap GAP2. In such an embodiment, a gap in which another light blocking material pattern is not disposed may be defined between the light blocking member LBM-2 and the additional light blocking member BM.

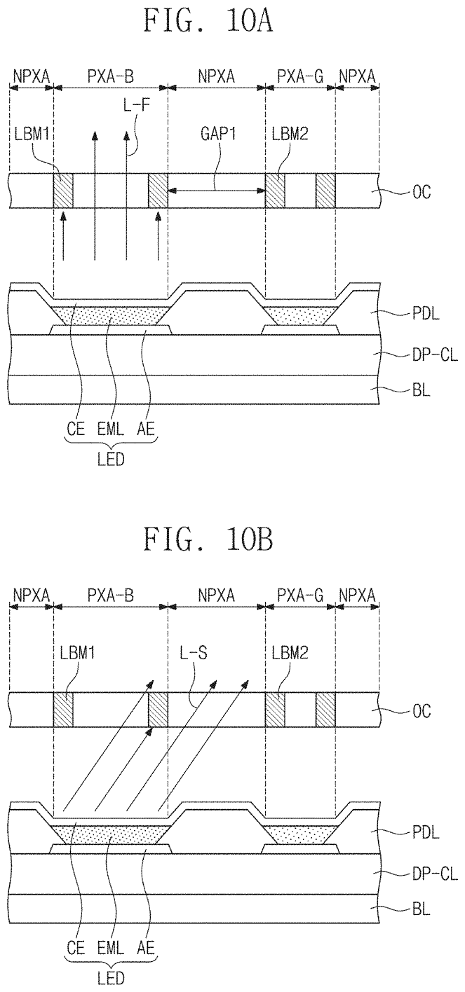

FIGS. 10A and 10B are cross-sectional views showing a portion of the display modules according to an embodiment of the disclosure. FIGS. 10A and 10B schematically show some elements among elements shown in FIG. 7A. For the convenience of illustration, the encapsulation layer TFE and the anti-reflective unit RPP are omitted in FIGS. 10A and 10B. FIGS. 10A and 10B show the light blocking member LBM shown in FIG. 7A to describe a function of the light blocking member in FIGS. 10A and 10B, however, descriptions in FIGS. 10A and 10B may be applied to the light blocking member LBM-1 shown in FIG. 8A and the light blocking member LBM-2 shown in FIG. 9B.

Referring to FIGS. 7A, 10A, and 10B, a portion of a front light L-F among lights emitted from the light emitting element LED may be blocked by the light blocking member LBM, and the other portion of the front light L-F may be emitted to the outside. The portion of the front light L-F may be blocked by the light blocking member LBM, and the other portion of the front light L-F may be emitted to the outside through an area in which the light blocking member LBM is not disposed. In the first light emitting areas PXA-B, the portion of the front light L-F may be blocked by the first sub-light blocking member LBM1, and the other portion of the front light L-F may be emitted to the outside through the first light emitting areas PXA-B in which the first sub-light blocking member LBM1 is not disposed.

In such an embodiment, a portion of a light in a side view, that is, a viewing angle light L-S, among the lights emitted from the light emitting element LED may be also blocked, and the other portion of the viewing angle light L-S may be emitted to the outside. The portion of the viewing angle light L-S may be blocked by the light blocking member LBM, and the other portion of the viewing angle light L-S may be emitted to the outside through the gap defined between the light blocking members LBM in the light emitting areas adjacent to each other. In the light emitting element LED disposed in the first light emitting areas PXA-B, the portion of the viewing angle light L-S may be blocked by the first sub-light blocking member LBM1, and the other portion of the viewing angle light L-S may be emitted to the outside through the first gap GAP1 defined between the first sub-light blocking member LBM1 and the second sub-light blocking member LBM2.

According to embodiments of the invention, the display device includes the light blocking member overlapping the light emitting areas, and particularly, the light blocking member disposed in one light emitting area is disposed spaced apart from the light blocking member disposed in another light emitting area adjacent to the one light emitting area. In such embodiments, the gap in which the separate light blocking material pattern is not disposed may be defined between the light blocking members respectively disposed in the light emitting areas. In such an embodiment of the display device, the portion of the light traveling in the front view direction may be blocked by the light blocking member overlapping the light emitting areas, and thus, the brightness in the front view may be reduced. In such an embodiment, the light traveling in the side view direction may be emitted to the outside through the gap defined between the light blocking members, and thus, the brightness in the side view may be improved. Accordingly, the brightness retention rate in the side surface may be improved compared with that in the front surface, and the display efficiency of the display device may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel comprising a light emitting area, from which a light is emitted, and a peripheral area adjacent to the light emitting area; and
a light blocking member disposed on the display panel to block the light,
wherein
at least a portion of the light blocking member is disposed in the light emitting area,
one side surface of the light blocking member is disposed in the light emitting area, and
an opposing side surface of the light blocking member, which is opposite to the one side surface, is disposed closer to a center of the peripheral area than the one side surface is.

2. The display device of claim 1, wherein
the light emitting area comprises:
a first light emitting area from which a first light is emitted; and
a second light emitting area from which a second light having a wavelength different from the first light is emitted, and
the light blocking member comprises:
a first sub-light blocking member disposed in the first light emitting area; and
a second sub-light blocking member disposed in the second light emitting area.

3. The display device of claim 2, wherein
the first sub-light blocking member and the second sub-light blocking member are spaced apart from each other with a first gap defined therebetween when viewed in a plan view, and
the first gap is defined to allow at least a portion thereof to overlap the peripheral area.

4. The display device of claim 1, further comprising:
an overcoat layer disposed on the display panel to cover the light blocking member.

5. The display device of claim 1, further comprising:
an input sensing unit disposed on the display panel,
wherein the light blocking member is disposed in the input sensing unit.

6. The display device of claim 5, wherein the light blocking member comprises a conductive layer.

7. The display device of claim 6, wherein
the conductive layer included in the light blocking member is provided in plural, and
an upper surface of an uppermost layer among the conductive layers is blackened.

8. The display device of claim 1, further comprising:
an anti-reflective layer disposed on the display panel.

9. The display device of claim 8, wherein
the anti-reflective layer comprises a plurality of color filters, and
the light blocking member is disposed in each of the plurality of color filters.

10. The display device of claim 9, wherein the light blocking member has a black color.

11. The display device of claim 9, wherein
the light emitting area comprises:
a first light emitting area from which a first light is emitted; and
a second light emitting area from which a second light having a wavelength different from the first light is emitted,
the light blocking member comprises:
a first sub-light blocking member disposed in the first light emitting area; and
a second sub-light blocking member disposed in the second light emitting area,
the plurality of color filters comprise:
a first color filter overlapping the first light emitting area; and
a second color filter overlapping the second light emitting area,
wherein the first sub-light blocking member comprises a material having a color different from a color of the first color filter, and
the second sub-light blocking member comprises a material having a color different from a color of the second color filter.

12. The display device of claim 1, wherein the light blocking member has a thickness equal to or greater than about 0.5 micrometers and equal to or smaller than about 2 micrometers.

13. The display device of claim 1, wherein the light blocking member has a width equal to or greater than about 0.5 micrometers and equal to or smaller than about 3 micrometers.

14. The display device of claim 1, further comprising:
an additional light blocking member overlapping the peripheral area.

15. The display device of claim 14, wherein the light blocking member and the additional light blocking member are spaced apart from each other with a second gap defined therebetween when viewed in a plan view.

16. The display device of claim 1, wherein the opposing side surface of the light blocking member is disposed at a boundary between the light emitting area and the peripheral area when viewed in a plan view.

17. A display device comprising:
a display panel comprising a light emitting area and a peripheral area adjacent to the light emitting area, wherein the light emitting area comprises a first light emitting area from which a first light is emitted and a second light emitting area from which a second light having a wavelength different from the first light is emitted; and
a light blocking member disposed on the display panel to block a light,
wherein the light blocking member comprises:
a first sub-light blocking member disposed in the first light emitting area; and
a second sub-light blocking member disposed in the second light emitting area,
wherein the first sub-light blocking member and the second sub-light blocking member are spaced apart from each other with a first gap defined therebetween when viewed in a plan view, and
the first gap is defined to allow at least a portion thereof to overlap the peripheral area.

18. The display device of claim 17, wherein
the light emitting area further comprises a third light emitting area from which a third light having a wavelength different from the first and second lights is emitted, and
the light blocking member further comprises a third sub-light blocking member disposed in the third light emitting area.

19. The display device of claim 18, wherein
the first light is a blue light,
the second light is a green light, and
the third light is a red light.

20. The display device of claim 17, further comprising:
an anti-reflective layer disposed on the display panel; and
a window disposed on the anti-reflective layer.
